(19) United States
(12) Patent Application Publication
(10) Pub. No.: US 2012/0112153 A1
(43) Pub. Date: May 10, 2012

(54) NONVOLATILE MEMORY DEVICE AND METHOD OF MANUFACTURING THE SAME

(76) Inventors: Takeki Ninomiya, Osaka (JP); Satoru Fujii, Osaka (JP); Yukio Hayakawa, Kyoto (JP); Takumi Mikawa, Shiga (JP)

(21) Appl. No.: 13/380,159

(22) PCT Filed: Jul. 13, 2011
(86) PCT No.: PCT/JP2011/004022

§ 371 Date: Dec. 22, 2011

(30) Foreign Application Priority Data
Jul. 14, 2010 (JP) 2010-160125

(51) Int. Cl. H01L 45/00

(52) U.S. Cl. 257/2; 438/382; 257/E45.003

(57) ABSTRACT

Provided is a nonvolatile memory device which requires a lower initializing voltage such that the nonvolatile memory device can be operated at a low voltage. The nonvolatile memory device (10) includes: a first electrode layer (105) formed above a semiconductor substrate (100); a first oxygen-deficient tantalum oxide layer (106x) formed on the first electrode layer (105) and having a composition represented by TaOₓ where 0.8≦x≦1.9; a second oxygen-deficient tantalum oxide layer (106y) formed on the first oxygen-deficient tantalum oxide layer (106x) and having a composition represented by TaO_{y} where 2.1≦y; and a second electrode layer (107) formed on the second tantalum oxide layer (106y). The second tantalum oxide layer (106y) has a pillar structure including a plurality of pillars.

### TECHNICAL FIELD

The present invention relates to a variable resistance nonvolatile memory device which has a resistance value that changes according to application of a voltage pulse.

### BACKGROUND ART

Recent years have seen increasing high performance in electronic devices such as mobile information devices and home information appliances following the development of digital technology. With the increased high performance in these electronic devices, miniaturization and increase in speed of semiconductor elements used are rapidly advancing. Among these, application of large-capacity nonvolatile memories typified by a flash memory is rapidly expanding. In addition, as a next-generation new-type nonvolatile memory to replace the flash memory, research and development on a nonvolatile memory device which uses what is called a variable resistance element is advancing. Here, a variable resistance element refers to an element having a property such that a resistance value reversibly changes according to electrical signals, and capable of nonvolatile storage of information corresponding to the resistance value.

PTL 1 discloses a variable resistance element in which tantalum oxide layers having different oxygen content percentages are stacked and used as a variable resistance layer. FIG. 13 shows a variable resistance nonvolatile memory device 20 provided with a conventional variable resistance element. The variable resistance nonvolatile memory device 20 includes: a semiconductor substrate 200 on which a first line 201 is formed; a first interlayer insulating layer 202 formed on the semiconductor substrate 200 so as to cover the first line 201; a first contact hole 203 for electrical connection between the first line and a first electrode layer 205 through the first interlayer insulating layer 202; and a first contact plug 204 mainly containing tungsten and filling the first contact hole 203. Furthermore, the first contact plug 204 is covered with a variable resistance element 212 formed on the first interlayer insulating layer 202. The variable resistance element 212 includes the first electrode layer 205, a variable resistance layer 206, and a second electrode layer 207. Then, a second interlayer insulating layer 208 is formed so as to cover the variable resistance element 212. A second contact hole 209 is formed through the second interlayer insulating layer 208 so that the second electrode layer 207 and a second line 211 are electrically connected. A second contact plug 210 is formed in the second contact hole 209. The second line 211 is formed on the second interlayer insulating layer 208 so as to cover the second contact plug 210.

The variable resistance layer 206 has a stacked structure of a first tantalum oxide layer 206x and a second tantalum oxide layer 206y. The second tantalum oxide layer 206y has an oxygen content percentage higher than the oxygen content percentage of the first tantalum oxide layer 206x.

NPL 1 discloses a nonvolatile memory in which a transition metal oxide is used as a variable resistance element. According to NPL 1, a conductive path switchable between a high resistance state and a low resistance state is formed in a thin film of a transition metal oxide, which is generally an insulator, by initializing a nonvolatile memory so that the resistance of the thin film changes according to a pulse. FIG. 15 shows dependency of initializing voltage on the thickness of transition metal oxides described in NPL 1. NPL 1 describes properties of four types of transition metal oxides, that is, NiO, TiO₂, HfO₂, and ZrO₂. As shown in FIG. 15, necessary initializing voltage depends on the type of transition metal oxide, and increases with increase in the thickness of the transition metal oxide. According to NPL 1, the transition metal oxides are preferably formed into a thinner film so that necessary initializing voltage can be reduced.

### [Citation List]

### [Patent Literature]

### [PTL 1] International Publication No. 2008/149484

### [Non Patent Literature]

### [NPL 1] I. G. Baek et al., IEDM 2004, p. 587

### SUMMARY OF INVENTION

### [Technical Problem]

A process of manufacturing a nonvolatile memory device includes a step of heating at approximately 400° C. for formation of lines of copper or aluminum. Such a heating process forms a hillock of an electrode material pointing from the first electrode layer 205 or the second electrode layer 207 included in the variable resistance element 212 toward the variable resistance layer 206 shown in FIG. 13. When a hillock is formed on the second electrode layer 207 in the variable resistance element 212, a conductive path formed in the variable resistance layer originates at the hillock. This is because the thickness of the second tantalum oxide layer 206y is smaller there due to the hillock formed toward the variable resistance layer. In addition, initial insulation of the variable resistance element 212 depends not only on the thickness of transition metal oxides but also on the shape, size, and density of such hillocks, and variation of initial resistance values increases. Furthermore, the shape, size, and density of the hillocks are difficult to control because they depend strongly on the electrode material, stress of the interlayer insulating layer, and parameters of processing such as temperature. It is thus preferable that no hillock be formed on electrodes of variable resistance elements so that initial resistance values of the variable resistance elements can be stabilized.

Examples of materials for electrodes of variable resistance elements include platinum (Pt), iridium (Ir), palladium (Pd), copper (Cu), silver (Ag), and gold (Au). In particular, Ir has a coefficient of thermal expansion of 6.4×10⁻⁶ (° C.⁻¹), which is smaller than the coefficient of thermal expansion of Pt, 8.8×10⁻⁶ (° C.⁻¹). Furthermore, Young's modulus of Ir is 529×10⁹ (N/m²), which is larger than Young's modulus of Pt, 152×10⁹ (N/m²). Due to these physical properties, thermal expansion of Ir is smaller than that of Pt, and is therefore likely to be subjected to smaller stress. Even when Ir is subjected to stress, it rarely forms a hillock when heated at 400° C. because Ir is difficult to be plastically deformed under stress. (a) in FIG. 14 is a transmission electron microscope (TEM) image of a cross section of the variable resistance element 212 for which Pt is used as a material for the second electrode layer 207. In (a) in FIG. 14, the first tantalum oxide layer 206x, the second tantalum oxide layer 206y, and the second electrode layer 207 are stacked above the first electrode layer 205, and it is obvious that the second tantalum oxide layer 206y is partially thin because of a hillock of the second electrode layer. (b) in FIG. 14 is a TEM image of a cross section of a variable resistance element in which Ir is used as a material for electrodes. Also in (b) in FIG. 14 as in (a) in FIG. 14, the first tantalum oxide layer 206x, the second tantalum oxide layer 206y, and the second electrode layer 207 are stacked above the first electrode layer 205. However, unlike in (a) in FIG. 14, the second electrode layer 207 in the example shown in (b) in FIG. 14 does not have a hillock such that the thickness of the second tantalum oxide layer is even. When no hillock is formed on electrodes, initial resistance values can be controlled by changing the thickness of the metal oxide layer, and variation of the initial resistance values can be reduced. At the same time, however, there is no region where the second tantalum oxide layer is thinner because the second tantalum oxide layer has no hillock. As a result, initializing voltage, that is, voltage for the process of initialization, in which a voltage higher in absolute values than a driving voltage for a usual resistance change operation is applied to a variable resistance film once or more times to form a conductive path in a variable resistance layer of a variable resistance element immediately after its manufacture, needs to be higher than when an electrode has a hillock, so that there is a problem that initialization of nonvolatile memory device at a low voltage is hindered.

The present invention, conceived to solve the problem, has an object of providing a nonvolatile memory device, which includes a variable resistance element produced without forming a hillock on an interface between an electrode and a variable resistance layer, and requires a lower initializing voltage so that the nonvolatile memory device can be initialized at a low voltage, and a method of manufacturing the nonvolatile memory device.

### [Solution to Problem]

In order to solve the problem, a nonvolatile memory device according to an aspect of the present invention is a variable-resistance nonvolatile memory device having a resistance value that changes according to a polarity of an applied electric pulse, and includes: a first electrode layer formed above a semiconductor substrate; a variable resistance layer formed on the first electrode layer; and a second electrode layer formed on the variable resistance layer; wherein the variable resistance layer includes: a first metal oxide layer which is an oxygen-deficient metal oxide layer formed on the first electrode layer; and a second metal oxide layer which is formed on the first metal oxide layer and has a degree of oxygen deficiency lower than a degree of oxygen deficiency of the first metal oxide layer, and the second metal oxide layer is a tantalum oxide layer which has a pillar structure including a plurality of pillars and has a composition represented by TaO_{y} where 2.1≦y.

Here, it is preferable the first metal oxide layer be a layer including a transition metal oxide, and it is more preferable that the first metal oxide layer be a tantalum oxide layer having a composition represented by TaOₓ where 0.8≦x≦1.9.

More specifically, the second metal oxide layer has a pillar structure including a plurality of pillars standing on the first metal oxide layer. Here, each of the pillars may have a pillar diameter smaller than 16 nm.

When the second metal oxide layer has such a pillar structure including a plurality of pillars, the nonvolatile memory device including an electrode made of a material which may form a hillock can be initialized by applying a reduced initializing voltage.

In order to solve the problem, a method of manufacturing a nonvolatile memory device according to an aspect of the present invention is a method of manufacturing a variable-resistance nonvolatile memory device having a resistance value that changes according to a polarity of an applied electric pulse, and includes:

forming, above a semiconductor substrate, a first electrode material layer to be formed into a first electrode layer; forming a variable resistance layer on the first electrode material layer; and forming, on the variable resistance layer, a second electrode material layer to be formed into a second electrode layer, wherein, the forming of a variable resistance layer includes: forming, on the first electrode material layer, a first metal oxide layer which is an oxygen-deficient metal oxide layer; and forming, on the first metal oxide layer, a second metal oxide layer having a degree of oxygen deficiency lower than a degree of oxygen deficiency of the first metal oxide layer, and in the forming of a second metal oxide layer, a tantalum oxide material layer is formed as the second metal oxide layer by sputtering, the tantalum oxide material layer being formed into a tantalum oxide layer having a pillar structure including a plurality of pillars.

Here, in the case where the tantalum oxide layer is formed using a method of CVD or ALD, a material for tantalum oxide such as pentaethoxy tantalum (TaOC₂H₅)₅) is necessary. In contrast, in the case where the method according to the present invention is used in which the tantalum oxide layer is formed by sputtering, tantalum oxide, tantalum metal, and oxygen gas can be used as materials for the tantalum oxide layer, so that manufacturing costs can be reduced.

Furthermore, in the forming of a second metal oxide layer, the tantalum oxide material layer may be formed by sputtering using a tantalum oxide as a sputtering target and a noble gas element as a sputtering gas, the tantalum oxide having a composition represented by Ta₂O₅. When sputtering is performed using a tantalum oxide having a composition represented by Ta₂O₅ as a sputtering target with only a noble gas element, resulting tantalum oxide layer has a composition represented by TaO_{y} (2.1≦y) and therefore has superior resistance change properties. Furthermore, unlike a method in which a tantalum oxide material layer is formed by reactive sputtering in which a sputtering target of tantalum is sputtered using oxygen as a sputtering gas, oxygen is not used in the method according to the aspect of the present invention. It is therefore possible to prevent oxidation of the first metal oxide layer (for example, the first tantalum oxide material layer) having a composition represented by TaOₓ (0.8≦x≦1.9) during the sputtering.

Furthermore, in the forming of a second metal oxide layer, the tantalum oxide material layer may be formed by sputtering at a film formation pressure of 0.2 Pa to 3 Pa. The desired pillar structure can be obtained at a low temperature when the sputtering is performed at a film formation pressure of 0.2 Pa to 3 Pa.

Furthermore, a nonvolatile memory device according to another aspect of the present invention is a variable-resistance nonvolatile memory device having a resistance value that changes according to a polarity of an applied electric pulse, and includes: a first electrode layer formed above a semiconductor substrate; a variable resistance layer formed on the first electrode layer; a second electrode layer formed on the variable resistance layer; wherein the variable resistance layer includes: a second metal oxide layer formed on the first electrode layer; and a first metal oxide layer which is formed on the second metal oxide layer and has a degree of oxygen deficiency higher than a degree of oxygen deficiency of the second metal oxide layer, and the second metal oxide layer is a tantalum oxide layer which has a pillar structure including a plurality of pillars and has a composition represented by TaO_{y} where 2.1≦y.

Here, it is preferable that the first metal oxide layer be a layer including a transition metal oxide, and it is more preferable that the first metal oxide layer is a tantalum oxide layer having a composition represented by TaOₓ where 0.8≦x≦1.9.

More specifically, the second metal oxide layer has a pillar structure including a plurality of pillars standing on the first electrode layer. Here, each of the pillars may have a pillar diameter smaller than 16 nm.

In this configuration, the first metal oxide material layer which has a higher degree of oxygen deficiency and is to be formed into the first metal oxide layer is formed on the second oxide material layer which has a lower degree of oxygen deficiency and is to be formed into the first metal oxide layer. As a result, a natural oxide film is not formed on the surface of the second tantalum oxide material layer, which has a lower degree of oxygen deficiency, even when the element is exposed to air after the second tantalum oxide material layer is formed. This eliminates influence of a natural oxide film at the interface between the second tantalum oxide layer and the first tantalum oxide layer and thereby allows stable formation of a conductive path. Furthermore, the pillar structure of the second metal oxide layer lowers initializing voltage of the nonvolatile memory device.

Furthermore, a method of manufacturing a nonvolatile memory device according to another aspect of the present invention is a method of manufacturing a variable-resistance nonvolatile memory device having a resistance value that changes according to a polarity of an applied electric pulse, and includes: forming, above a semiconductor substrate, a first electrode material layer to be formed into a first electrode layer; forming a variable resistance layer on the first electrode material layer; and forming, on the variable resistance layer, a second electrode material layer to be formed into a second electrode layer, wherein, the forming of a variable resistance layer includes: forming a second metal oxide layer on the first electrode layer; and forming, on the second metal oxide layer, a first metal oxide layer having a degree of oxygen deficiency higher than a degree of oxygen deficiency of the second metal oxide layer, and in the forming of a second metal oxide layer, a tantalum oxide material layer is formed as the second metal oxide layer by sputtering, the tantalum oxide material layer being formed into a tantalum oxide layer which has a pillar structure including a plurality of pillars and has a composition represented by Ta O_{y} where 2.1≦y.

Here, in the case where the tantalum oxide layer is formed using a method of CVD or ALD, a material for tantalum oxide such as pentaethoxy tantalum (Ta(OC₂H₅)₅) is necessary. In contrast, in the case where the method according to the present invention is used in which. the tantalum oxide layer is formed by sputtering, tantalum oxide, tantalum metal, and oxygen gas can be used as materials for the tantalum oxide layer, so that manufacturing costs can be reduced.

Here, in the forming of a second metal oxide layer, the tantalum oxide material layer may be formed by sputtering at a film formation pressure of 0.2 Pa to 3 Pa using a tantalum oxide as a sputtering target and a noble gas element as a sputtering gas, the tantalum oxide having a composition represented by Ta₂O₅. The desired pillar structure can be obtained at a low temperature when the tantalum oxide material layer is formed by sputtering at a film formation pressure of 0.2 Pa to 3 Pa.

### [Advantageous Effects of Invention]

According to the present invention, a nonvolatile memory device which can be initialized at a lower voltage and a method of manufacturing the nonvolatile memory device are provided.

### BRIEF DESCRIPTION OF DRAWINGS

FIG. 1 illustrates a cross-sectional view that shows a schematic configuration of a nonvolatile memory device according to Embodiment 1 of the present invention.

[FIG. 2] (a) to (j) in FIG. 2 illustrate cross-sectional views that show a method of manufacturing the nonvolatile memory device according to Embodiment 1 of the present invention: (a) in FIG. 2 shows a process of forming a first line on a substrate; (b) in FIG. 2 shows a process of forming a first interlayer insulating layer; (C) in FIG. 2 shows a process of forming a first contact hole; (d) to (e) in FIG. 2 shows a process of forming a first contact plug; (f) in FIG. 2 shows a process of forming a first electrode material layer and a first tantalum oxide material layer; (g) in FIG. 2 shows a process of forming a second tantalum oxide material layer; (h) in FIG. 2 shows a process of forming a second electrode material layer; (i) in FIG. 2 shows a process of forming a variable resistance element including a first electrode layer, a first tantalum oxide layer, a second tantalum oxide layer, and a second electrode layer; and (j) in FIG. 2 shows a process of forming a second interlayer insulating layer, a second contact hole, a second contact plug, and a second line.

[FIG. 3] (a) to (f) in FIG. 3 are perspective SEM images of second tantalum oxide material layers formed by the process shown in (g) in

FIG. 2 and relevant to Embodiment 1 of the present invention: (a) in

FIG. 3 is a perspective SEM image of a second tantalum oxide material layer formed by sputtering at a film formation pressure of 0.2 Pa; (b) in FIG. 3 is a perspective SEM image of a second tantalum oxide material layer formed by sputtering at a film formation pressure of 0.3 Pa; (c) in FIG. 3 is a perspective SEM image of a second tantalum oxide material layer formed by sputtering at a film formation pressure of 0.7 Pa; (d) in FIG. 3 is a perspective SEM image of a second tantalum oxide material layer formed by sputtering at a film formation pressure of 0.95 Pa; (e) in FIG. 3 is a perspective SEM image of a second tantalum oxide material layer formed by sputtering at a film formation pressure of 1.3 Pa; and (f) in FIG. 3 is a perspective SEM image of a second tantalum oxide material layer formed by sputtering at a film formation pressure of 3 Pa.

[FIG. 4] (a) to (c) in FIG. 4 are perspective SEM images of tantalum oxide material layers formed by sputtering: (a) in FIG. 4 is a perspective SEM image of a second tantalum oxide material layer formed by sputtering at a film formation pressure of 0.05 Pa; (b) in FIG. 4 is a perspective SEM image of a second tantalum oxide material layer formed by sputtering at a film formation pressure of 0.1 Pa; and (c) in FIG. 4 is a perspective SEM image of a second tantalum oxide material layer formed by sputtering at a film formation pressure of 5 Pa.

FIG. 5 shows a relationship between the film formation pressure for sputtering in the process of forming the second tantalum oxide material layer and the initializing voltage of the nonvolatile memory device according to Embodiment 1 of the present invention.

FIG. 6 shows part of processes of manufacturing a variable resistance element included in a conventional nonvolatile memory device: (a) in FIG. 6 shows a process of forming a first tantalum oxide material layer on a first electrode material layer; and (b) in FIG. 6 shows a process of forming a second tantalum oxide material layer on the first tantalum oxide material layer.

FIG. 7 is a perspective SEM image of a film which is formed using the method shown in FIG. 6 so that the first tantalum oxide material layer and the second tantalum oxide material layer are stacked in the film.

FIG. 8 shows a relationship between pillar diameters of the second tantalum oxide material layer and initializing voltage of the nonvolatile memory device.

FIG. 9 shows a result of measurement of valence band spectra of on the second tantalum oxide material layer relevant to Embodiment 1 of the present invention performed using XPS.

FIG. 10 shows a result of measurement of the second tantalum oxide material layer relevant to Embodiment 1 of the present invention using an XRD technique.

FIG. 11 illustrates a cross-sectional view that shows a schematic configuration of a nonvolatile memory device according to Embodiment 2 of the present invention.

[FIG. 12] (a) to (e) in FIG. 12 illustrate cross-sectional views that show processes of manufacturing the nonvolatile memory device according to Embodiment 2 of the present invention: (a) in FIG. 12 shows a process of forming a first electrode material layer; (b) in FIG. 12 shows a process of forming a second tantalum oxide material layer; (c) in FIG. 12 shows a process of forming a first tantalum oxide material layer and a second electrode material layer; (d) in FIG. 12 shows a process of forming, by patterning and dry etching using a mask, a variable resistance element including a first electrode layer, a second tantalum oxide layer, a first tantalum oxide layer, and a second electrode layer; and (e) in FIG. 12 shows a process of forming a second interlayer insulating layer, a second contact hole, a second contact plug, and a second line.

FIG. 13 illustrates a cross-sectional view that shows a schematic configuration of a nonvolatile memory device including a conventional variable resistance element disclosed in PTL 1.

[FIG. 14] (a) and (b) in FIG. 14 are cross-sectional TEM images of conventional variable resistance elements: (a) in FIG. 14 is a cross-sectional TEM image of a variable resistance element in which a second electrode layer contains platinum; and (b) in FIG. 14 is a cross-sectional TEM image of a variable resistance element in which a second electrode layer contains iridium.

FIG. 15 shows a relationship of initializing voltage and the thickness of transition metal oxide films of conventional variable resistance elements described in NPL 1.

### DESCRIPTION OF EMBODIMENTS

Hereinafter, embodiments of the present invention shall be described with reference to the Drawings. It should be noted that all the embodiments described below show preferred specific examples of the present invention. The values, materials, constituent elements, layout and connection of the constituent elements, steps, and the order of the steps in the embodiments are given not for limiting the present invention but merely for illustrative purposes only. The scope of the present invention is limited only by the claims. Thus, among the constituent elements in the following embodiments, a constituent element not included in the independent claim providing the highest level description of the present invention is not always necessary for the present invention to solve the problem but shall be described as a constituent element of a preferable embodiment.

### Embodiment 1

(Configuration of Nonvolatile Memory Device)

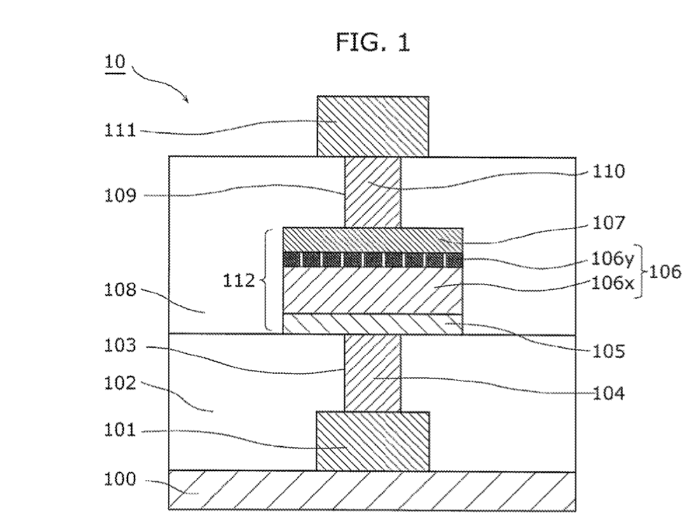

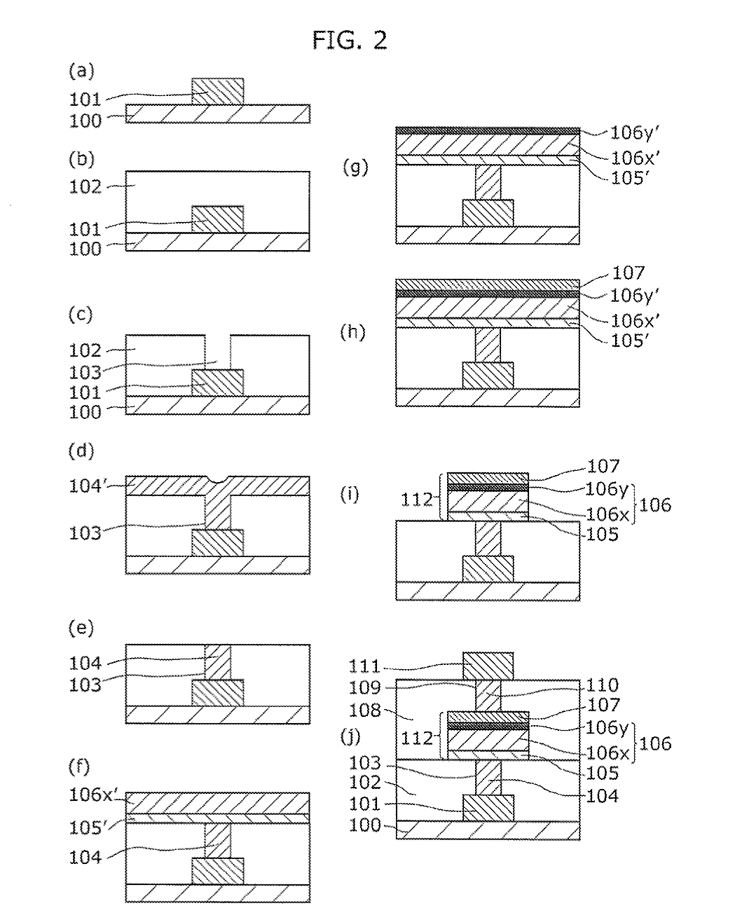

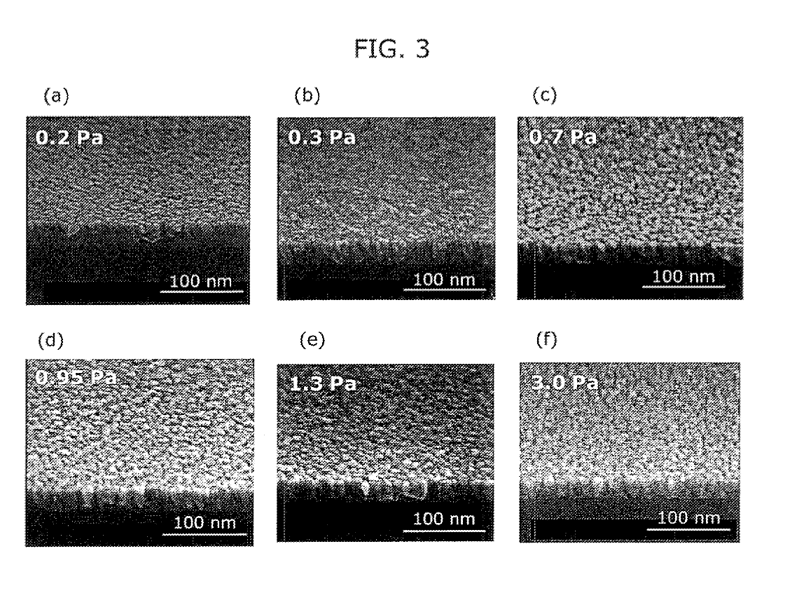

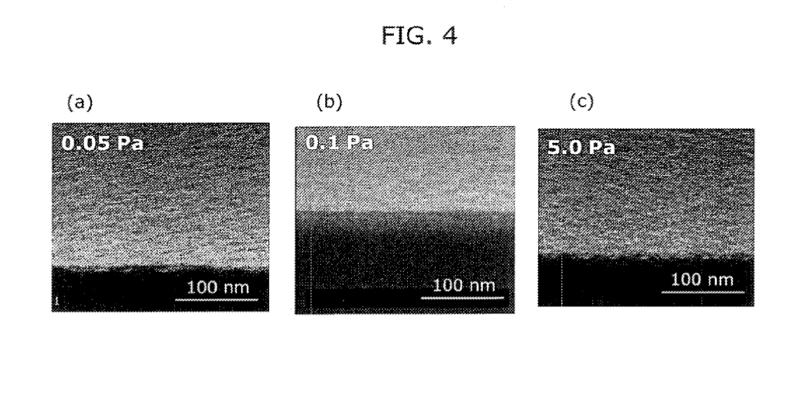

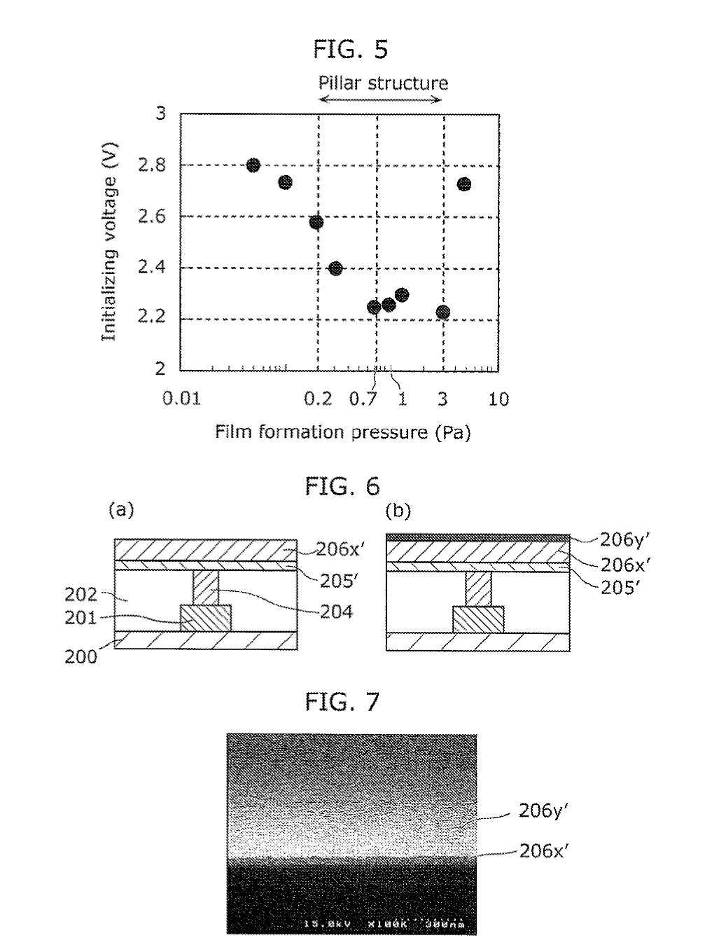

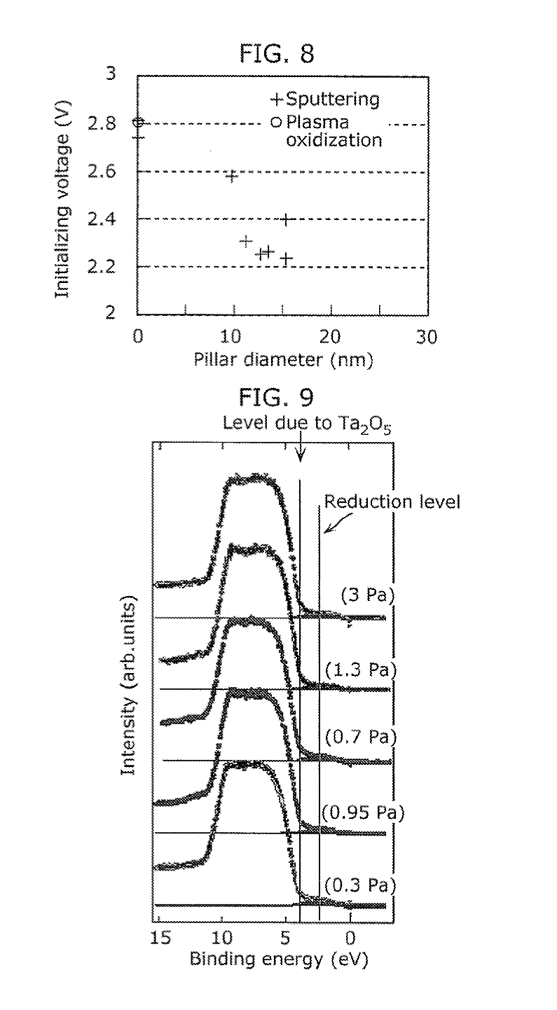

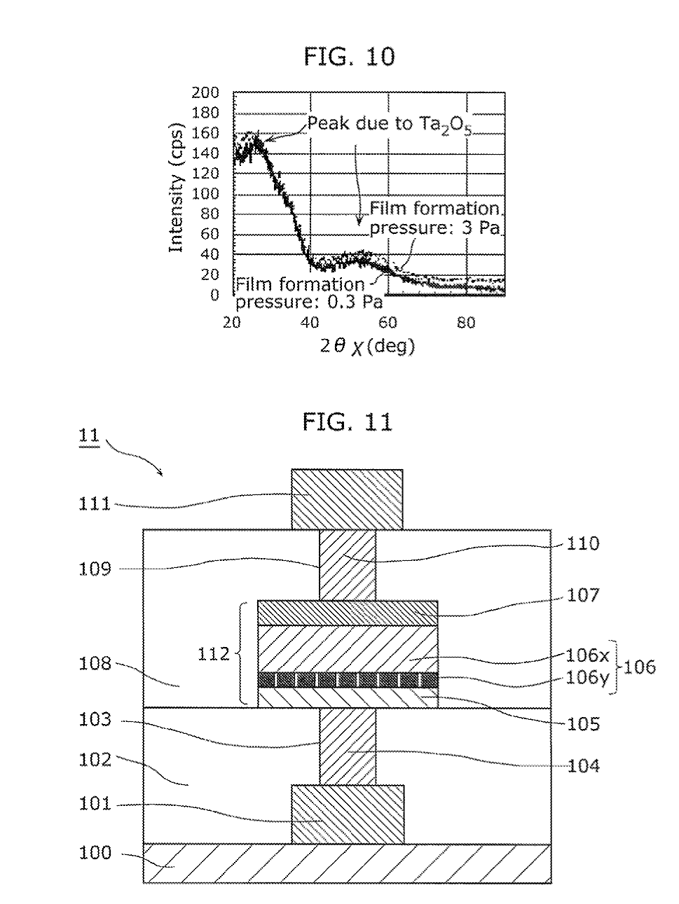

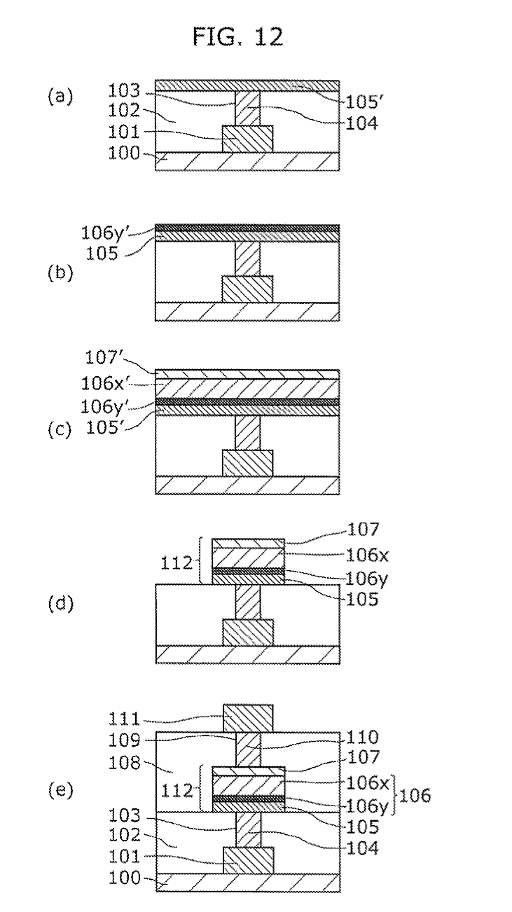

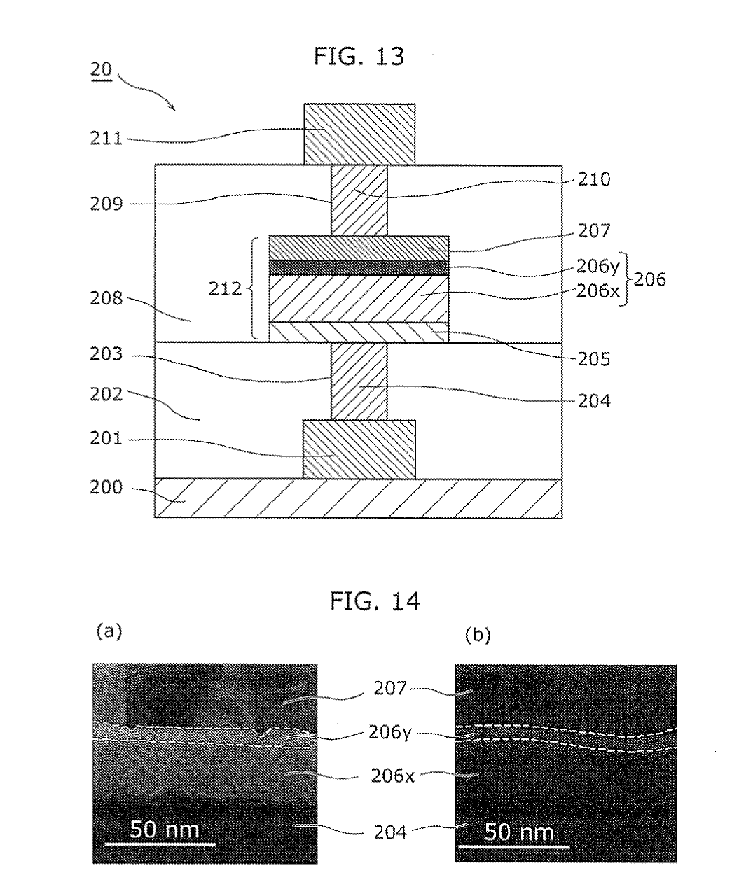

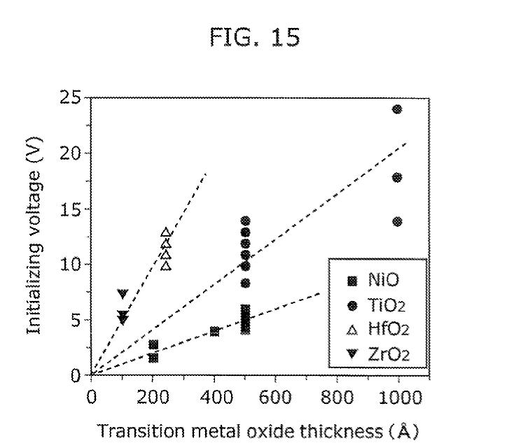

FIG. 1 illustrates a cross-sectional view that shows a schematic configuration of a nonvolatile memory device 10 according to Embodiment 1 of the present invention. The nonvolatile memory device 10 includes: a semiconductor substrate 100 on which a first line 101 is formed; a first interlayer insulating layer 102 including a silicon oxide film (500 to 1000 nm thick) formed on the semiconductor substrate 100 so as to cover the first line 101; a first contact hole 103 (50 to 300 nm diameter) for electrical connection between the first line 101 and a first electrode layer 105 through the first interlayer insulating layer 102; and a first contact plug 104 made mainly of tungsten and filling the first contact hole 103. Furthermore, the first contact plug 104 is covered with a variable resistance element 112 formed on the first interlayer insulating layer 102. The variable resistance element 112 includes the first electrode layer 105 (5 to 100 nm thick) containing tantalum nitride, a variable resistance layer 106 (20 to 100 nm thick), and a second electrode layer 107 (5 to 100 nm thick) containing a noble metal (at least one of Pt, Ir, and Pd). The variable resistance element 112 is covered with a second interlayer insulating layer 108 containing a silicon oxide film (500 to 1000 nm thick). A second contact hole 109 (50 to 300 nm thick) is formed through the second interlayer insulating layer 108 for electrical connection between the second electrode layer 107 and a second line 111. A second contact plug 110 made mainly of tungsten is formed in the second contact hole 109. The second line 111 is formed on the second interlayer insulating layer 108 so as to cover the second contact plug 110.

Here, the variable resistance layer 106 includes: a first metal oxide layer (a first tantalum oxide layer 106x in FIG. 1) which is an oxygen-deficient metal oxide layer formed on the first electrode layer 105; and a second metal oxide layer (a second tantalum oxide layer 106y in FIG. 1) which is formed on the first metal oxide layer and has a degree of oxygen deficiency lower than a degree of oxygen deficiency of the first metal oxide layer. Specifically, in Embodiment 1, the variable resistance layer 106 includes a first tantalum oxide layer 106x formed on the first electrode layer 105 and a second tantalum oxide layer 106y formed on the first tantalum oxide layer 106x. The first tantalum oxide layer 106x is oxygen deficient and contains TaOₓ where Ta is tantalum, O is oxygen, and x is a positive number within a range of 0.8 to 1.9 indicating a composition ratio of O to Ta. The second tantalum oxide layer 106y contains TaO_{y} where Ta is tantalum, O is oxygen, and y is a positive number equal to or larger than 2.1 indicating a composition ratio of O to Ta. The second tantalum oxide layer 106y has a pillar structure including a plurality of pillars. More specifically, the second tantalum oxide layer 106y has a pillar structure including a plurality of pillars standing on the first tantalum oxide layer 106x.

It should be noted that an “oxygen-deficient” oxide refers to an oxide having a low oxygen content (in atom ratio, that is, the ratio of the number of oxygen atoms to the total number of atoms) compared to an oxide having a stoichiometric composition. A stoichiometric oxide composition of tantalum oxide is Ta₂O₅, and therefore the ratio of oxygen (O) to tantalum (Ta) in the number of atoms (O/Ta) is 2.5. Therefore, an oxygen-deficient tantalum oxide has an atom ratio of oxygen (O) to tantalum (Ta) is greater than zero and smaller than 2.5.

It should be also noted that “a degree of oxygen deficiency” of a metal oxide refers to a proportion of deficient oxygen to oxygen contained in the metal oxide having a stoichiometric composition. For example, in the case of a metal of tantalum (Ta), the stoichiometric composition of the metal oxide is Ta₂O₅, which has a degree of oxygen deficiency of 0% (here, the oxygen content. percentage is O/(Ta+O)=71.4%). For example, in the case where the stoichiometric composition of the metal oxide is TaO_{1.5}, the degree of oxygen deficiency is (2.5-1.5)12.5=40% (here, the oxygen content percentage is O/(Ta+O)=60%).

In this configuration, necessary initializing voltage is low in comparison with the conventional nonvolatile memory device 20 in which the second tantalum oxide layer 206y does not have such a pillar structure as shown in FIG. 13.

In the nonvolatile memory device 10, the variable resistance element 112 can be changed from a high resistance state to a low resistance state by applying a negative voltage pulse to the second electrode layer 107 with reference to the first electrode layer 105 (resistance change to low resistance state), and can be changed from a low resistance state to a high resistance state by applying a positive voltage pulse to the second electrode layer 107 with reference to the first electrode layer 105 (resistance change to high resistance state). The resistance change to low resistance state is considered to be due to an increase in the degree of oxygen deficiency in at least part (for example, a conductive path) of the second tantalum oxide layer 106y as a result of expulsion of oxygen ions from the second tantalum oxide layer 106y caused by the application of the negative voltage pulse to the second electrode layer 107. On the other hand, the resistance change to high resistance state is considered to be due to decrease in the degree of oxygen deficiency of the second tantalum oxide layer 106y (in particular, in a conductive path of the second tantalum oxide layer 106y) as a result of move of oxygen ions from the first tantalum oxide layer 106x into the second tantalum oxide layer 106y caused by the application of the positive voltage pulse to the second electrode layer 107.

FIG. 1 shows the constituent elements other than the variable resistance element 112, but the nonvolatile memory device according to the present invention needs to include at least the variable resistance element and does not necessarily include the substrate, lines, or contact plugs. In other words, the nonvolatile memory device according to the present invention is a memory device including at least: two electrode layers (the first electrode layer 105 and the second electrode layer 107) formed above the semiconductor substrate 100; and two metal oxide layers (the first tantalum oxide layer 106x having a higher degree of oxygen deficiency and the second tantalum oxide layer 106y having a lower degree of oxygen deficiency in FIG. 1) interposed between the two electrode layers, and the second metal oxide layer (the second tantalum oxide layer 106y in FIG. 1) has a pillar structure including a plurality of pillars.

Since an electrode layer made of a material which can be oxidized and reduced more easily has a lower standard electrode potential, changeability of resistance can be controlled by appropriate selection of standard electrode potential of the electrode layers. The following is thus true for the materials for the two electrode layers: the second electrode layer 107, which is in contact with the second tantalum oxide layer 106y, preferably contains one or more of materials having a standard electrode potential higher than that of the tantalum, such as gold (Au), platinum (Pt), iridium (Ir), palladium (Pd), copper (Cu), and silver (Ag), and the first electrode layer 105, which is in contact with the first tantalum oxide layer 106x, preferably contains a material having a standard electrode potential lower than that of the material for the second electrode layer 107 (for example, W, Ni, and TaN). In this configuration, resistance change can be stably caused in the second tantalum oxide layer 106y in contact with the second electrode layer 107.

More specifically, tantalum has a standard electrode potential of −0.6 eV, which is lower than the standard electrode potentials of platinum and iridium. The standard electrode potential indicates how easily tantalum can be oxidized and reduced. Accordingly, the variable resistance layer 106 is oxidized and reduced at the interface with the second electrode layer 107 containing platinum or iridium with transfer of oxygen therebetween such that the resistance of the variable resistance layer 106 changes. This facilitates oxidation-reduction reaction in the second metal oxide layer at a region near the interface between the second electrode layer 107 and the second metal oxide layer, so that change of the resistance of the variable resistance layer 106 stably changes.

As described above, the variable resistance layer 106 having a stacked structure of the first metal oxide layer which is oxygen deficient and the second metal oxide layer which has a degree of oxygen deficiency lower than that of the first metal oxide layer provides a nonvolatile memory device which allows a stable reversible rewriting using resistance change.

It should be noted that the metal contained in the first metal oxide layer having a degree of oxygen deficiency higher than that of the second metal oxide layer may be a metal other than tantalum. Preferable metals to be contained in the first metal oxide layer include transition metals such as titanium (Ti), hafnium (Hf), zirconium (Zr), niobium (Nb), and tungsten (W). With property that the transition metals can be in more than one oxidation states, different resistance states can be obtained in oxidation-reduction reaction.

In other words, different materials can be used for the first metal contained in the first metal oxide layer (for example, a first transition metal) and the second metal contained in the second metal oxide layer (that is, tantalum). In this case, the second metal oxide layer preferably has a degree of oxygen deficiency lower than that of the first metal oxide layer, that is, has a higher resistance. In this configuration, voltage applied between the first electrode layer 105 and the second electrode layer 107 during resistance change is distributed more to the second metal oxide layer than to the first metal oxide layer so that oxidation-reduction reactions in the second metal oxide layer can be caused more easily.

Furthermore, when the materials for the first transition metal and the second transition metal are different from each other, it is preferable that the second transition metal have a standard electrode potential lower than the standard electrode potential of the first transition metal. The higher the standard electrode potential of a material is, the more difficult to oxidize the material is. When an oxide having a standard electrode potential lower than the first metal oxide layer is formed in the second metal oxide layer, oxidation-reduction reactions in the second metal oxide layer is facilitated. This is because resistance change is caused by change in a high resistivity of a minute filament (conductive path) formed in the second metal oxide layer due to oxidation-reduction reactions. For example, resistance can stably change when an oxygen-deficient tungsten oxide or an oxygen-deficient iron oxide is used for the first metal oxide layer and TaO_{y} (2.1≦y) is used for the second metal oxide layer. This is because both tungsten and iron have standard electrode potentials, 0.1 eV and −0.037 eV, respectively, higher than the standard electrode potential of tantalum, −0.6 eV. The data on the standard electrode potentials is shown in NPL 2, “CRC Press., Handbook of Chemistry and Physics, 84th Edition, 2003, pp. 1219-1222”.

(Method of Manufacturing Nonvolatile Memory Device)

(a) to (j) in FIG. 2 illustrate cross-sectional views which show a method of manufacturing main parts of the nonvolatile memory device 10 according to Embodiment 1 of the present invention. The method of manufacturing the main parts of the nonvolatile memory device 10 shall be described using these drawing. In the method of manufacturing the nonvolatile memory device 10 described below, both of the first metal oxide layer and the second metal oxide layer contain tantalum oxide.

As shown in (a) in FIG. 2, the first line 101 is formed by the following process: first, a conductive layer (400 to 600 nm thick) containing, for example, aluminum is formed, by sputtering, on the semiconductor substrate 100 on which a transistor or an underlying line is formed; and then, the conductive layer is formed into the first line 101 by patterning and dry etching using a desired mask. The first line 101 may be a copper line formed by damascening.

Next, as shown in (b) in FIG. 2, the first interlayer insulating layer 102 is formed by the following process: first, an insulating layer of plasma tetraethoxysilane (TEOS) is formed on the semiconductor substrate 100 by chemical vapor deposition (CVD) so as to cover the first line 101; and then the surface of the insulating layer is planarized to be the first interlayer insulating layer 102 having a thickness of 500 to 1000 nm. Instead of plasma TEOS, a fluoride-containing oxide (for example, fluorosilicate glass (FSG)) or a low-k material (insulating material having a small dielectric constant) may be used as a material for the first interlayer insulating layer 102 in order to reduce parasitic capacitance between lines.

Next, as shown in (c) in FIG. 2, the first contact hole 103 is formed by a process in which the first interlayer insulating layer 102 is processed by patterning and dry etching using a desired mask so that the first contact hole 103 having a diameter of 50 to 300 nm is open through the first interlayer insulating layer 102 to the first line 101. Here, if the width of the first line 101 is smaller than the diameter of the first contact hole 103, the contact area of the first line 101 with the first contact plug 104 varies due to misalignment of the masks, which may cause variation in cell current, for example. In order to prevent it, the first line 101 is formed so that the width of the first line 101 is greater than the diameter of the first contact hole 103.

Next, as shown in (d) in FIG. 2, the first contact plug 104 is formed in the following process: first, an underlying layer which includes a titanium (Ti) layer having a thickness of 5 to 30 nm and a titanium nitride (TiN) layer having a thickness of 5 to 30 nm and functions as an adhesion layer and a diffusion barrier, is formed by sputtering and CVD, respectively; and then a film of tungsten (W) which has a thickness of 200 to 400 nm and serves as the main component of the contact plug is formed as an upper layer by CVD. As a result, the first contact hole 103 is filled with a conductive layer 104′ having a stacked structure (W/TiN/Ti structure), which is made into the first contact plug 104.

Next, as shown in (e) in FIG. 2, the first contact plug 104 is formed by a process in which the entire surface of the wafer is polished to be planar by chemical mechanical polishing (CMP) to remove unnecessary portion of the conductive layer 104′ above the first interlayer insulating layer 102 so that the first contact plug 104 is formed in the first contact hole 103.

Next, as shown in (f) in FIG. 2, a first electrode material layer 105′ and a first tantalum oxide material layer 106x′, which is an example of the first metal oxide layer, are formed by the following process: first, the first electrode material layer 105′ which contains tantalum nitride (TaN) and has a thickness of 20 to 50 nm is formed above the first interlayer insulating layer 102 by sputtering so as to cover the first contact plug 104; and then, the first tantalum oxide material layer 106x′ is formed on the first electrode material layer 105′ by sputtering. The first tantalum oxide material layer 106x′ was formed by reactive sputtering in which a sputtering target of tantalum is sputtered under an oxygen gas atmosphere. The thickness of the first tantalum oxide material layer measured by spectroscopic ellipsometry was 40 to 50 nm. The sputtering was performed at a power of 1000 W, a film formation pressure of 0.05 Pa, an argon gas flow rate of 20 sccm, and an oxygen gas flow rate of 23 sccm. The composition of the first tantalum oxide material layer (that is, the value of x in TaOₓ) was x=1.6, which was measured using an apparatus for a Rutherford backscattering spectrometry (RBS) with a first tantalum oxide material layer 106x′ having a thickness of 100 nm formed under the same conditions.

Next, as shown in (g) in FIG. 2, a second tantalum oxide material layer 106y′, which is an example of the second metal oxide layer, is formed on the first tantalum oxide material layer 106x′. The second tantalum oxide material layer 106y′ was formed by RF magnetron sputtering using a tantalum oxide having a composition of Ta₂O₅ as a sputtering target and argon (Ar), which is a noble gas, as a sputtering gas. The sputtering was performed at an RF output of 200 W and the substrate temperature set at room temperature. The film formation pressure during the sputtering is adjusted by changing the flow rate of the argon gas and using a conductance valve. The second tantalum oxide material layer 106y′ has a thickness of 3 to 10 nm, which effectively causes resistance change when stacked with the first tantalum oxide material layer 106x′. The thickness was measured by spectroscopic ellipsometry. Here, the second tantalum oxide material layer 106y′ formed by the process shown in (g) in FIG. 2 has a pillar structure including a plurality of pillars when it is formed at a film formation pressure of 0.2 to 3 Pa by the sputtering system used for the present experiment. Here, film formation pressure at which the resulting second tantalum oxide material layer 106y′ has a pillar structure including a plurality of pillars depends on a sputtering system to be used, and can be determined experimentally.

Next, as shown in (h) in FIG. 2, the second electrode material layer 107′ was formed on the second tantalum oxide material layer 106y′ by sputtering iridium (Ir).

Next, as shown in (i) in FIG. 2, the variable resistance element 112 including the first electrode layer 105, the first tantalum oxide layer 106x, the second tantalum oxide layer 106y, and the second electrode layer 107 was formed by patterning and dry etching the first electrode material layer 105′, the first tantalum oxide material layer 106x′, the second tantalum oxide material layer 106y′, and the second electrode material layer 107′ using a desired mask. When a noble metal is used as the second electrode material layer 107′, the second electrode material layer 107′ can be used as a hard mask to form a variable resistance element because noble metals, which have superior resistance change properties, are difficult to etch.

Finally, as shown in (j) in FIG. 2, the second interlayer insulating layer 108 having a thickness of 500 to 1000 nm was formed so as to cover the variable resistance element 112, and the second contact hole 109 and the second contact plug 110 were formed by the same process as shown in (a) to (e) in FIG. 2. Subsequently, the second line 111 was formed so as to cover the second contact plug 110, and then the nonvolatile memory device 10 was completed.

(a) to (f) in FIG. 3 are perspective scanning electron microscope (SEM) images of oxide material layers formed by the process shown in (g) in FIG. 2. (a) in FIG. 3 is a perspective SEM image of a tantalum oxide material layer 106y′ formed by sputtering at a film formation pressure of 0.2 Pa. (b) in FIG. 3 is a perspective SEM image of a tantalum oxide material layer 106y′ formed by sputtering at a film formation pressure of 0.3 Pa. (c) in FIG. 3 is a perspective SEM image of a tantalum oxide material layer 106y′ formed by sputtering at a film formation pressure of 0.7 Pa. (d) in FIG. 3 is a perspective SEM image of a tantalum oxide material layer 106y′ formed by sputtering at a film formation pressure of 0.95 Pa. (e) in FIG. 3 is a perspective SEM image of a tantalum oxide material layer 106y′ formed by sputtering at a film formation pressure of 1.3 Pa. (f) in FIG. 3 is a perspective SEM image of a tantalum oxide material layer 106y′ formed by sputtering at a film formation pressure of 3 Pa.

(a) to (c) in FIG. 4 are perspective SEM images of tantalum oxide material layers formed at film formation pressures out of the range in the process shown in (g) in FIG. 2. Specifically, (a) in FIG. 4 is a perspective SEM image of a tantalum oxide material layer formed by sputtering at a film formation pressure of 0.05 Pa. (b) in FIG. 4 is a perspective SEM image of a tantalum oxide material layer formed by sputtering at a film formation pressure of 0.1 Pa. (c) in FIG. 4 is a perspective SEM image of a tantalum oxide material layer formed by sputtering at a film formation pressure of 5 Pa. The tantalum oxide material layers shown in (a) to (c) in FIG. 4 were formed at the same conditions as in the process shown in (g) in FIG. 2 except the condition of the film formation pressure.

For the tantalum oxide material layers shown in the perspective SEM images (a) to (f) in FIG. 3 and (a) to (c) in FIG. 4, the film formation time was adjusted so as to form tantalum oxide material layers having a thickness of approximately 30 nm so that whether or not a pillar structure was present could be easily determined.

The perspective SEM images (a) to (f) in FIG. 3 shows that the second tantalum oxide material layer 106y′ has a structure in which a plurality of pillars stands. That is, formed by the above process, the second tantalum oxide layer 106y included in the nonvolatile memory device 10 according to Embodiment 1 has a pillar structure including a plurality of pillars standing on the first tantalum oxide layer 106x. This therefore shows that the second tantalum oxide layer 106y has a pillar structure when it is fbrmed at a pressure within a range from 0.2 Pa to 3 Pa even when the substrate temperature is set at room temperature. Furthermore, as shown in (a) to (c) in FIG. 4, no pillar structure was found in the tantalum oxide material layers formed at a film formation pressure of 0.05 Pa, 0.1 Pa, or 5 Pa, which are out of the film formation pressure range of 0.2 Pa to 3 Pa.

FIG. 5 shows a relationship between the film formation pressure for sputtering in the process of forming the second tantalum oxide material layer 106y′ and the initializing voltage of the nonvolatile memory device 10. In the case shown in FIG. 5, the second tantalum oxide layer 106y has a thickness of 5 nm. As shown in FIG. 5, the initializing voltage of the nonvolatile memory device 10 is reduced when the second tantalum oxide material layer 106y′ is formed at a film formation pressure of 0.2 Pa to 3 Pa, which provides the second tantalum oxide material layer 106y′ with a pillar structure. Also can be seen from FIG. 5, it is preferable that the second tantalum oxide material layer 106y′ be formed by sputtering at a film formation pressure of 0.7 Pa to 3 Pa so that the initializing voltage is reduced.

(a) and (b) in FIG. 6 show a method of manufacturing the conventional tantalum oxide material layer 206x′ and second tantalum oxide material layer 206y′ described in PTL 1. In the method of manufacturing the first tantalum oxide material layer 206x′ described in PTL 1, the first tantalum oxide material layer 206x′ is oxidized in oxygen plasma (plasma oxidation). (a) in FIG. 6 shows a process in which the first tantalum oxide material layer 206x′ is formed to be 50 nm thick on the first electrode material layer 205′ under the same conditions as in the process shown in (f) in FIG. 2. Subsequently, the second tantalum oxide material layer 206y′ having a thickness of 5 nm is formed in the process show in (b) in FIG. 6 by plasma oxidation. FIG. 7 is a perspective SEM image of the film which is formed using the method shown in (a) and (b) in FIG. 6 so that the first tantalum oxide material layer 206x′ and the second tantalum oxide material layer 206y′ are stacked in the film. As shown in FIG. 7, no pillar structure is present in the stacked structure in which the first tantalum oxide material layer 206x′ and the second tantalum oxide material layer 206y′ are stacked by the conventional method.

FIG. 8 shows a relationship between the initializing voltage of the nonvolatile memory device 10 and the pillar diameter of the second tantalum oxide material layer 106y′ obtained by the manufacturing process shown in (g) in FIG. 2 according to Embodiment 1. Here, the pillar diameter is an average diameter of the pillars included in the pillar structure. The pillar diameters were obtained using the SEM image, based on the number of pillars within a range of a certain distance. For example, the number of pillars within an arbitrarily selected range of 100 nm in the SEM image is visually counted, and then the distance of 100 nm is divided by the number, and therefore an average width of the pillars, that is, a pillar diameter was calculated. The pillar diameter of the second tantalum oxide material layer without a pillar structure is defined as 0 nm.

An open circle in FIG. 8 indicates an initializing voltage of the conventional nonvolatile memory device 20 including the second tantalum oxide material layer 206y′ formed by plasma oxidation. Crosses in FIG. 8 indicate initializing voltages of the nonvolatile memory devices including the second tantalum oxide material layers formed at different film formation pressures in sputtering. Among the crosses in FIG, 8, the crosses for pillar diameters of 9.8 to 16 nm represent data for the nonvolatile memory devices each including the second tantalum oxide material layers 106y′ formed at film formation pressures of 0.2 Pa to 3 Pa so that the resulting second tantalum oxide material layers 106y′ have pillar structures.

As can be seen in FIG. 8, the initializing voltage can be reduced by producing the nonvolatile memory device 10 so that the nonvolatile memory device 10 includes the second tantalum oxide material layer 106y′ having a pillar structure (that is, the pillar diameter of the second tantalum oxide material layer 106y′ is larger than 0 nm). That is, the second tantalum oxide layer 106y included in the nonvolatile memory device 10 according to Embodiment 1 includes pillars having a pillar diameter smaller than 16 nm, or, more specifically, larger than 9.8 nm and smaller than 16 nm. The structure of the second tantalum oxide layer 106y including the pillars having such a pillar diameter allows initialization of the nonvolatile memory device 10 at a voltage lower than a voltage of the conventional nonvolatile memory device. Furthermore, the initializing voltage of the nonvolatile memory device 10 according to the present invention is 0.2 V or more lower than the initializing voltage of the nonvolatile memory device 20 including the variable resistance element 212 formed by plasma oxidation of the second tantalum oxide material layer 206y′.

A probable mechanism of the reduction of the initializing voltage is as follows. In the nonvolatile memory device according to Embodiment 1, the second tantalum oxide material layer 106y has such a pillar structure including a plurality of pillars that the interface between the second tantalum oxide material layer 106y and the second electrode layer has protrusions and recesses. When a voltage for initializing the nonvolatile memory device 10 is applied, an electric field formed and the second electrode layer is prone to concentrating at the protrusions and recesses formed in the interface between the second tantalum oxide material layer 106y. As a result, the nonvolatile memory device is initialized (in other words, a conductive path is formed in the second tantalum oxide material layer 106y) at a lower voltage.

FIG. 9 shows a result of measurement performed on the second tantalum oxide material layer 106y′ using XPS. The result of the measurement using X-ray photoelectron spectroscopy (XPS) shows a level (a reduction level of approximately 2.5 eV), even though it is a weak sign, resulting from oxygen deficiency of tantalum oxide having a composition of Ta₂O₅ in the second tantalum oxide material layer 106y′ in Embodiment 1. It is understood from the result that the second tantalum oxide material layer 106y′ in Embodiment 1 has a composition resulting from reduction of tantalum oxide having a composition represented by Ta₂O₅.

FIG. 10 shows a result of analysis of the second tantalum oxide material layer 106y′ having a pillar structure using an X-ray diffraction (XRD) technique. The second tantalum oxide material layer 106y′ mentioned in FIG. 10 was formed at a film formation pressure of 0.3 Pa or 3 Pa, a sputtering pressure of 200 W, and a substrate temperature set at room temperature. The second tantalum oxide material layer 106y′ has a thickness of 30 nm, which was measured using the XRD technique. The measurement using the XRD technique was performed by a thin film method using ATX-E made by Rigaku Corporation, at an accelerating voltage of 50 kV and a discharging current of 250 mA. In addition, the method using the

XRD technique was performed at an incident angle of 1°, and a 2θ scan rate of 4 deg/min. According to the result shown in FIG. 10, an XRD peak intensity due to Ta₂O₅ is very low, and therefore it is predicable that the second tantalum oxide material layer 106y′ formed under the above conditions does not have crystallinity (that is, it does not have a crystalline structure with a vertical orientation).

Here, it is considered that the second tantalum oxide material layer 106y′ does not have crystallinity (that is, it does not have a crystalline structure with a vertical orientation) for the following reasons. According to what is called Thornton's model of thin film micro structure, an oxide can crystallize by sputtering generally at a temperature which is 30% of the melting point of the oxide or above only. It is therefore necessary that, for the nonvolatile memory device 10, the substrate temperature is 30% of 1468° C. (=1741 K), which is the melting point of Ta₂O₅, that is, 249° C. (=1741 K×0.3). On the other hand, in Embodiment 1, the second tantalum oxide material layer 106y′ is formed by sputtering, with a substrate temperature set at room temperature. Furthermore, a tantalum oxide material layer having a crystalline structure with a vertical orientation may have an XRD peak intensity of 1000 cps or higher, while the XRD peak intensity as a result of the analysis is approximately 160 cps. For these reasons, it is considered that the second tantalum oxide material layer 106y′ does not have crystallinity (that is, it does not have a crystalline structure with a vertical orientation). Accordingly, the second tantalum oxide material layer 106y′ according to Embodiment 1 has a pillar structure, but does not need to have crystallinity (that is, it does not need to have a crystalline structure with a vertical orientation).

### Embodiment 2

(Configuration of a Nonvolatile Memory Device)

FIG. 11 illustrates a cross-sectional view of a nonvolatile memory device 11 according to Embodiment 2 of the present invention. In FIG. 11, the same reference signs are used for constituent elements that are the same as in FIG. 1, and description thereof shall not be repeated. As shown in FIG. 11, the difference between the nonvolatile memory device 11 according to Embodiment 2 and the nonvolatile memory device 10 according to Embodiment 1 is in their inverted configurations of a first metal oxide layer (for example, a first tantalum oxide layer 106x) and a second metal oxide layer (for example, a second tantalum oxide layer 106y). In the nonvolatile memory device 11 according to Embodiment 2, the first metal oxide layer (for example, the first tantalum oxide layer 106x) is formed on the second metal oxide layer (for example, the second tantalum oxide layer 106y) to form a variable resistance layer 106. A method of manufacturing the nonvolatile memory device 11 shall be described below, in which both of the first metal oxide layer and the second metal oxide layer contain tantalum oxide.

(Method of Manufacturing Nonvolatile Memory Device)

(a) to (e) in FIG. 12 illustrate cross-sectional views that show a method of manufacturing main parts of the nonvolatile memory device 11 according to Embodiment 2 of the present invention. The method of manufacturing the main parts of the nonvolatile memory device 11 according to Embodiment 2 shall be described using these drawing. Processes prior to (a) in FIG. 12 are the same as in (a) to (g) in FIG. 2, and thus description thereof shall not be repeated.

Next, as shown in (a) in FIG. 12, the first electrode material layer 105′ is formed by forming a first electrode material layer 105′ containing iridium (Ir) on a first interlayer insulating layer 102 so as to cover the first contact plug 104. The first electrode material layer 105′ is to be formed into a first electrode layer.

Next, as shown in (b) in FIG. 12, a second tantalum oxide material layer 106y′, which is an example of the second metal oxide layer, is formed on the first electrode material layer 105x′. The second tantalum oxide material layer 106y′ was formed by RF magnetron sputtering using a tantalum oxide having a composition of Ta₂O₅ as a sputtering target and argon (Ar), which is a noble gas, as a sputtering gas. The sputtering was performed at an RF output of 200 W and the temperature of the sulbstrate set at room temperature. The film formation pressure during the sputtering was adjusted to 0.2 to 3 Pa by changing the flow rate of the argon gas and using a conductance valve. The second tantalum oxide material layer 106y′ has a thickness of 3 to 10 nm, which effectively causes resistance change. The thickness was measured by spectroscopic ellipsometry. Here, the second tantalum oxide material layer 106y′ formed by the process shown in (b) in FIG, 12 has a pillar structure including a plurality of pillars. More specifically, the second tantalum oxide material layer 106y′ has a pillar structure including a plurality of pillars standing on the first electrode layer 105.

Next, as shown in (c) in FIG. 12, a first tantalum oxide material layer 106x′ is formed on the second tantalum oxide material layer 106y′ by sputtering in the process of forming the first tantalum oxide material layer 106x′, which is an example of the first metal oxide layer, and a second electrode material layer 107′. The first tantalum oxide material layer 106x′ was formed by reactive sputtering in which a sputtering target of tantalum is sputtered under an oxygen gas atmosphere. The thickness of the first tantalum oxide material layer measured by spectroscopic ellipsometry was 40 to 50 nm. The sputtering was performed at a power of 1000 W, a film formation pressure of 0.05 Pa, an argon gas flow rate of 20 sccm, and an oxygen gas flow rate of 23 sccm. The composition of the first tantalum oxide material layer (that is, the value of x in TaOₓ) was x=1.6, which was measured by performing RBS on a first tantalum oxide material layer 106x′ having a thickness of 100 nm formed under the same conditions. Subsequently, the second electrode material layer 107′ containing tantalum nitride (TaN) and having a thickness of 20 to 50 nm was formed on the first tantalum oxide material layer 106x′ by sputtering.

Next, as shown in (d) in FIG. 12, a variable resistance element 112 including a first electrode layer 105, a second tantalum oxide layer 106y, a first tantalum oxide layer 106x, and a second electrode layer 107 was formed by patterning and dry etching the first electrode material layer 105′, the second tantalum oxide material layer 106y′, the first tantalum oxide material layer 106x′, and the second electrode material layer 107′ using a desired mask.

Finally, as shown in (e) in FIG. 12, a second interlayer insulating layer 108 having a thickness of 500 to 1000 nm was formed so as to cover the variable resistance element 112, and the second contact hole 109 and the second contact plug 110 were formed by the same process as shown in (c) to (e) in FIG. 2. Subsequently, a second line 111 was formed so as to cover the second contact plug 110 by the same process as shown in (a) in FIG. 2, and the nonvolatile memory device 11 is completed. It should be noted that the resulting second tantalum oxide layer 106y of the nonvolatile memory device 11 according to Embodiment 2 has the same properties (such as a relationship between film formation pressure and structure and initializing voltage) are the same as those of the second tantalum oxide layer 106y according to Embodiment 1.

In the nonvolatile memory device 11 in Embodiment 2, the first tantalum oxide material layer 106x′ is formed on the second tantalum oxide material layer 106y′, so that a natural oxide film is not formed on the surface of the second tantalum oxide material layer 106y′, which has a lower degree of oxygen deficiency, even when the element is exposed to air after the second tantalum oxide material layer 106y′ is formed. This eliminates influence of a natural oxide film at the interface between the second tantalum oxide layer 106y and the first tantalum oxide layer 106x and thereby allows stable formation of a conductive path.

Although the nonvolatile memory device and the method of manufacturing the nonvolatile memory device according to the present invention have been described based on Embodiment 1 and Embodiment 2, the present invention is not limited to these embodiments. Embodiments resulting from various modifications of the embodiments as well as embodiments resulting from any combinations of constituent elements of the different embodiments that may be conceived by those skilled in the art are also intended to be included within the scope of the present invention as long as they do not depart from the essence of the present invention.

For example, a nonvolatile memory device having a three-dimensional structure in which variable resistance elements are stacked so that nonvolatile memory devices 10 according to Embodiment 1 shown in FIG. 1 and nonvolatile memory devices 11 according to Embodiment 2 shown in FIG. 11 are alternatively or regularly stacked, is also within the scope of the present invention.

In the above embodiments, the tantalum oxide layers interposed between the first electrode layer and the second electrode layer may also contain a small amount of elements other than tantalum oxide. Such a small amount of other elements can be added for purposes such as fine control of resistance values, which is also within the scope of the present invention. For example, adding nitrogen to a variable resistance layer increases the resistance value of the variable resistance layer so that the reactivity of resistance change is increased.

Furthermore, there may be the case where a small amount of an element may be unintentionally mixed into a variable resistance layer due to residual gas or gas released from the wall of a vacuum chamber when the variable resistance layer is formed by sputtering. Such a case where a small amount of an element is mixed into a resistive film is also within the scope of the present invention as a matter of course.

### INDUSTRIAL APPLICABILITY

In the nonvolatile memory device and the method of manufacturing the nonvolatile memory device according to the present invention, a conductive path can be formed in a variable resistance element without hillocks on an electrode, so that initializing voltage of the nonvolatile memory device is reduced. The present invention thus has an advantageous effect that the nonvolatile memory device can operate at a low voltage. The nonvolatile memory device and the method of the same according to the present invention is therefore applicable as a nonvolatile memory device such as a ReRAM using a variable resistance element and the method of manufacturing the nonvolatile memory device.

### REFERENCE SIGNS LIST

10 Nonvolatile memory device according to Embodiment 1 of the present invention

11 Nonvolatile memory device according to Embodiment 2 of the present invention

20 Conventional nonvolatile memory device

100, 200 Semiconductor substrate

101, 201 First line

102, 202 First interlayer insulating layer

103, 203 First contact hole

104, 204 First contact plug

104′ Conductive layer

105, 205 First electrode layer

105′, 205′ First electrode material layer

106, 206 Variable resistance layer

106x, 206x First tantalum oxide layer (first metal oxide layer)

106x′, 206x′ First tantalum oxide material layer (first metal oxide material layer)

106y, 206y Second tantalum oxide layer (second metal oxide layer)

106x′, 206x′ Second tantalum oxide material layer (second metal oxide material layer)

107, 207 Second electrode layer

107′ Second electrode material layer

108, 208 Second interlayer insulating layer

109, 209 Second contact hole

110, 210 Second contact plug

112, 211 Second line

112, 212 Variable resistance element

1. A variable-resistance nonvolatile memory device having a resistance value that changes according to a polarity of an applied electric pulse, said nonvolatile memory device comprising:
a first electrode layer formed above a semiconductor substrate;
a variable resistance layer formed on said first electrode layer; and
a second electrode layer formed on said variable resistance layer;
wherein said variable resistance layer includes: a first metal oxide layer which is an oxygen-deficient metal oxide layer formed on said first electrode layer; and a second metal oxide layer which is formed on said first metal oxide layer and has a degree of oxygen deficiency lower than a degree of oxygen deficiency of said first metal oxide layer, and
said second metal oxide layer is a tantalum oxide layer which has a pillar structure including a plurality of pillars and has a composition represented by TaO_{y} where 2.1≦y.

2. The volatile memory device according to claim 1,
wherein said first metal oxide layer is a layer comprising a transition metal oxide.

3. The volatile memory device according to claim 2,
wherein said first metal oxide layer is a tantalum oxide layer having a composition represented by TaOₓ where 0.8≦x≦1.9.

4. The nonvolatile memory device according to claim 1,
wherein said second metal oxide layer has a pillar structure including a plurality of pillars standing on said first metal oxide layer.

5. The nonvolatile memory device according to claim 1.
wherein each of said pillars has a pillar diameter smaller than 16 nm.

6. A method of manufacturing a variable-resistance nonvolatile memory device having a resistance value that changes according to a polarity of an applied electric pulse, said method comprising:
forming, above a semiconductor substrate, a first electrode material layer to be formed into a first electrode layer;
forming a variable resistance layer on the first electrode material layer; and
forming, on the variable resistance layer, a second electrode material layer to be formed into a second electrode layer,
wherein, said forming of a variable resistance layer includes:
forming, on the first electrode material layer, a first metal oxide layer which is an oxygen-deficient metal oxide layer; and
forming, on the first metal oxide layer, a second metal oxide layer having a degree of oxygen deficiency lower than a degree of oxygen deficiency of the first metal oxide layer, and
in said forming of a second metal oxide layer, a tantalum oxide material layer is formed as the second metal oxide layer by sputtering, the tantalum oxide material layer being formed into a tantalum oxide layer having a pillar structure including a plurality of pillars.

7. The method of manufacturing a nonvolatile memory device according to claim 6,
wherein, in said forming of a second metal oxide layer, the tantalum oxide material layer is formed by sputtering using a tantalum oxide as a sputtering target and a noble gas element as a sputtering gas, the tantalum oxide having a composition represented by Ta₂O₅.

8. The method of manufacturing a nonvolatile memory device according to claim 6,
wherein, in said forming of a second metal oxide layer, the tantalum oxide material layer is formed by sputtering at a film formation pressure of 0.2 Pa to 3 Pa.

9. A variable-resistance nonvolatile memory device having a resistance value that changes according to a polarity of an applied electric pulse, said nonvolatile memory device comprising:
a first electrode layer formed above a semiconductor substrate;
a variable resistance layer formed on said first electrode layer;
a second electrode layer formed on said variable resistance layer;
wherein said variable resistance layer includes: a second metal oxide layer formed on said first electrode layer; and a first metal oxide layer which is formed on said second metal oxide layer and has a degree of oxygen deficiency higher than a degree of oxygen deficiency of said second metal oxide layer, and
said second metal oxide layer is a tantalum oxide layer which has a pillar structure including a plurality of pillars and has a composition represented by TaO_{y} where 2.1≦y.

10. The nonvolatile memory device according to claim 9,
wherein said first metal oxide layer is a layer comprising a transition metal oxide.

11. The nonvolatile memory device according to claim 10,
wherein said first metal oxide layer is a tantalum oxide layer having a composition represented by TaOₓ where 0.8≦x≦1.9.

12. The nonvolatile memory device according to claim 9,
wherein said second metal oxide layer has a pillar structure including a plurality of pillars standing on said first electrode layer.

13. The nonvolatile memory device according to claim 9,
wherein each of said pillars has a pillar diameter smaller than 16 nm.

14. A method of manufacturing a variable-resistance nonvolatile memory device having a resistance value that changes according to a polarity of an applied electric pulse, said method comprising:
forming, above a semiconductor substrate, a first electrode material layer to be formed into a first electrode layer;
forming a variable resistance layer on the first electrode material layer; and
forming, on the variable resistance layer, a second electrode material layer to be formed into a second electrode layer,
wherein, said forming of a variable resistance layer includes:
forming a second metal oxide layer on the first electrode layer; and
forming, on the second metal oxide layer, a first metal oxide layer having a degree of oxygen deficiency higher than a degree of oxygen deficiency of the second metal oxide layer, and
in said forming of a second metal oxide layer, a tantalum oxide material layer is formed as the second metal oxide layer by sputtering, the tantalum oxide material layer being formed into a tantalum oxide layer which has a pillar structure including a plurality of pillars and has a composition represented by TaO_{y} where 2.1≦y.

15. The method of manufacturing a nonvolatile memory device according to claim 14,
wherein, in said forming of a second metal oxide layer, the tantalum oxide material layer is formed by sputtering at a film formation pressure of 0.2 Pa to 3 Pa using a tantalum oxide as a sputtering target and a noble gas element as a sputtering gas, the tantalum oxide having a composition represented by Ta₂O₅.
